(19) United States
(12) Patent Application Publication
(10) Pub. No.: US 2026/0013093 A1
(43) Pub. Date: Jan. 8, 2026

(54) ELECTROMAGNETIC WAVE SHIELDING SHEET, METHOD FOR MANUFACTURING SAME, AND ELECTRONIC DEVICE HAVING SAME

(71) Applicant: AMOGREENTECH CO., LTD., Gimpo-si (KR)

(72) Inventors: Jin Han KIM, Gimpo-si (KR); Geunyoung JANG, Gimpo-si (KR); Hyo-Jung LEE, Gimpo-si (KR); Gyu Min LEE, Gimpo-si (KR); In-Yong SEO, Gimpo-si (KR); Kyung Su KIM, Gimpo-si (KR); Seayoung LIM, Gimpo-si (KR)

(73) Assignee: AMOGREENTECH CO., LTD., Gimpo-si (KR)

(21) Appl. No.: 19/107,602

(22) PCT Filed: Sep. 1, 2023
(86) PCT No.: PCT/KR2023/013097

§ 371 Date: Feb. 28, 2025

(30) Foreign Application Priority Data
Sep. 2, 2022 (KR) 10-2022-0111261

(51) Int. Cl. H05K 9/00

(52) U.S. Cl. CPC H05K 9/009; H05K 9/0088

(57) ABSTRACT

An electromagnetic wave shielding sheet is provided. The provided has excellent flexibility and thus attaches well to curved or stepped surfaces, can be implemented in a thin structure and thus is suitable for use in electronic devices which continue to decrease in thickness, and has an excellent vertical shielding performance notwithstanding the decrease in thickness and thus can minimize or prevent electromagnetic waves from leaking through side surfaces.

### CROSS-REFERENCE TO THE RELATED APPLICATIONS

This application is the national phase entry of International Application No. PCT/KR2023/013097, filed on Sep. 1, 2023, which is based upon and claims priority to Korean Patent Application No. 10-2022-0111261, filed on Sep. 2, 2022, the entire contents of which are incorporated herein by reference.

### TECHNICAL FIELD

The present invention relates to an electromagnetic wave shielding sheet, a method of manufacturing the same, and an electronic device having the same.

### BACKGROUND

Electromagnetic waves refer to a phenomenon in which energy moves in the form of a sinusoidal wave as electric and magnetic fields interact with each other and are useful in electronic devices for wireless communication and radar. While an electric field is generated by a voltage and has characteristics of being easily blocked by an increase of a distance or by obstacles such as trees, a magnetic field is generated by a current and has a strength characteristic that is inversely proportional to a distance but not being easily blocked.

Meanwhile, recent electronic devices are sensitive to electromagnetic interference (EMI) generated by an internal or external interference source of the electronic device, and there is a concern in that malfunctions of the electronic devices may be caused by electromagnetic waves. In addition, users of the electronic devices may also be affected by the electromagnetic waves generated by the electronic devices.

Thus, interest in electromagnetic wave shielding materials for protecting components of electronic devices or the human body from electromagnetic waves emitted by electromagnetic wave sources or external devices has increased rapidly.

The electromagnetic wave shielding material is typically manufactured of a conductive material, and electromagnetic waves emitted toward the electromagnetic wave shielding material are reflected by the electromagnetic wave shielding material or flow to the ground, thereby blocking the electromagnetic waves. Meanwhile, an example of the electromagnetic wave shielding material may be a metal case or a metal plate. However, the electromagnetic wave shielding material has difficulty in exhibiting flexibility and stretchability and is not easily deformed/restored into various shapes after manufactured once, so that there is a problem in that it is difficult for the electromagnetic wave shielding material to be easily employed in various applications. In particular, it is difficult for the electromagnetic wave shielding material such as a metal plate to be in close contact with components that require protection from components or sources generating electromagnetic waves without spacing, and cracks may occur due to bending in portions with steps or irregularities, which causes difficulty in fully performing electromagnetic wave shielding performance.

In order to solve these problems, there have been recently increasing attempts to secure flexibility together with electromagnetic wave shielding performance by imparting conductivity to a substrate in the form of a fiber web. However, even when flexibility is secured, it is not easy for an electromagnetic wave shielding member in the form of a fiber web to reach a required level of electromagnetic wave shielding performance.

Therefore, attempts are being recently conducted to secure sufficient electromagnetic wave shielding performance together with flexibility by stacking a plurality of electromagnetic wave shielding materials having different shapes or specifications onto a fiber web-shaped electromagnetic wave shielding material. However, in order to laminate and mutually fix the electromagnetic wave shielding materials having different shapes or specifications, an adhesive is used at interfaces therebetween. However, even when vertical electromagnetic wave shielding performance is secured by stacking the plurality of electromagnetic wave shielding materials, there is a concern in that electromagnetic waves may leak to the outside along the adhesive in a lateral direction, making it difficult to secure electromagnetic wave shielding performance.

### SUMMARY

### Technical Problem

The present invention is directed to providing an electromagnetic wave shielding sheet that can protect a user and prevent malfunction of other components within a device or other adjacent devices by blocking the electromagnetic waves generated by an electromagnetic wave generation source from being emitted to the outside, a method of manufacturing the same, and an electronic device including the same.

The present invention is also directed to providing an electromagnetic wave shielding sheet that can have excellent flexibility and excellent adhesion characteristics even on curved or stepped adherend surfaces, can be implemented with a small thickness to be suitable for use in thin electronic devices, and can minimize or prevent electromagnetic waves from leaking to a side surface while having excellent vertical shielding performance even with a small thickness, a method of manufacturing the same, and an electronic device including the same.

### Technical Solution

One aspect of the present invention to solve the above problems provides an electromagnetic wave shielding sheet including an electromagnetic wave shielding part having a first surface and a second surface facing the first surface in a thickness direction and including a first conductive part of which one surface is the second surface and which has a three-dimensional network structure formed of a first metal-coated fiber of which a metal layer (1) exposed to an outside, and a second conductive part of which one surface is the first surface, a cover member disposed on the first surface of the electromagnetic wave shielding part, and a conductive adhesive member in which a part of an entire thickness region is disposed on the second surface of the electromagnetic wave shielding part, and the remaining thickness region is disposed inside the second conductive part.

According to one embodiment of the present invention, an entire thickness of the electromagnetic wave shielding sheet may be 45 μm or less.

In addition, the second conductive part may have a three-dimensional network structure formed of a second metal-coated fiber of which a metal layer is exposed to the outside, and a size of an open pore in first surface may be formed to be smaller than a size of an open pore in the second surface of the first conductive part. In this case, an average size of pores in the second surface may range from 2 μm to 6 μm, and an average size of pores in the first surface may range from 0.2 μm to 2 μm.

In addition, the metal layer of the first conductive part and the metal layer of the second conductive part may be formed integrally.

In addition, the first conductive part may include a first fiber web formed of a first fiber, the second conductive part may include a second fiber web formed of a second fiber, a fusion part configured to fix the first fiber web and the second fiber web may be further included, and the metal layer may integrally cover outer surfaces of the first fiber and the second fiber of the stacked first fiber web and second fiber web and an outer surface of the fusion part.

In addition, the first conductive part may include a first fiber web formed of a first fiber, the second conductive part may be a metal sheet, a fusion part configured to fix the metal sheet and the first fiber web may be further included, and the metal layer of the first conductive part may integrally cover the outer surface of the first fiber and an outer surface of the fusion part.

In addition, a thickness of the metal layer may range from 0.1 μm to 2 μm.

In addition, the metal layer may be formed of one or more metal materials selected from the group consisting of aluminum, nickel, copper, silver, gold, chromium, platinum, a titanium alloy, and stainless steel.

In addition, a diameter of the first fiber may range from 2 μm to 10 μm, and the first fiber web may have a basis weight ranging from 5 g/m² to 20 g/m² and a porosity ranging from 30% to 70%.

In addition, a diameter of the second fiber may be less than 1 μm, and the second fiber web may have a basis weight ranging from 1 g/m² to 10 g/m² and a porosity ranging from 20% to 60%.

In addition, the fusion part may be formed through a plurality of dot-shaped hot-melt adhesive members or grid-shaped hot-melt adhesive members, which are spaced apart from each other.

In addition, a thickness of the remaining region of the conductive adhesive member located inside the first conductive part may be 10% to 40% of the entire thickness of the conductive adhesive member.

In addition, the conductive adhesive member may contain an adhesive component and conductive fillers dispersed in the adhesive component and having 5 wt % to 20 wt % of an entire weight of the conductive adhesive member.

In addition, the cover member may be a material-selective adhesive member that is not adhered to an adherend surface of a specific material.

Another aspect of the present invention provides a method of manufacturing an electromagnetic wave shielding sheet, which includes manufacturing an electromagnetic wave shielding part having a first surface and a second surface facing the first surface in a thickness direction and including a first conductive part of which one surface is the second surface and which has a three-dimensional network structure formed of a first metal-coated fiber of which a metal layer exposed to the outside, and a second conductive part of which one surface is the first surface, disposing and pressing a conductive adhesive member on the second surface of the electromagnetic wave shielding part such that a part of an entire region of the conductive adhesive member is located inside the first conductive part, and arranging a cover member on the first surface of the electromagnetic wave shielding part.

According to one embodiment of the present invention, the manufacturing of the electromagnetic wave shielding part may include operation (1) of stacking a second fiber web formed of a second fiber having a smaller diameter than a first fiber for forming a second conductive part on one surface of a first fiber web formed of the first fiber for forming a first conductive part, and operation (2) of forming a metal layer surrounding an outer surface of each of the first fiber and the second fiber by integrally electroless plating the stacked first fiber web and second fiber web.

In addition, operation (1) may include arranging a dot-shaped or grid-shaped hot-melt adhesive member between the first fiber web and the second fiber web and melting the hot-melt adhesive member to fuse the first fiber web and the second fiber web.

Alternatively, the manufacturing of the electromagnetic wave shielding part may include operation (A) of stacking a metal sheet as the second conductive part on one surface of the first fiber web formed of first fibers for forming the first conductive part, and operation (B) of integrally electroless plating the stacked first fiber web and metal sheet to form a metal layer surrounding an outer surface of the first fiber.

In addition, operation (A) may include arranging a dot-shaped or grid-shaped hot-melt adhesive member between the first fiber web and a metal sheet, and melting the hot-melt adhesive member to fuse the first fiber web and the metal sheet.

In addition, the dot-shaped or grid-shaped hot-melt adhesive member may have a melting point ranging from 80° C. to 160° C. and a thickness of 20 μm or less.

In addition, still another aspect of the present invention provides an electronic device including the electromagnetic wave shielding sheet according to the present invention.

### Advantageous Effects

An electromagnetic wave shielding sheet according to the present invention can block the electromagnetic waves generated by an electromagnetic wave source from being emitted to the outside, thereby protecting a user and preventing malfunction of other parts within a device or other adjacent devices. In addition, since the electromagnetic wave shielding sheet has excellent flexibility, the electromagnetic wave shielding sheet has good adhesion characteristics even on curved or stepped adherend surfaces, can be implemented with a small thickness, can be suitable for use in thin electronic devices. Furthermore, the electromagnetic wave shielding sheet has excellent vertical shielding performance despite its reduced thickness, can also minimize or prevent electromagnetic waves leaking to a side surface, and thus can be widely applied across industries, including the electrical and electronics fields.

### BRIEF DESCRIPTION OF THE DRAWINGS

FIG. 1 is a cross-sectional view illustrating an electromagnetic wave shielding sheet according to one embodiment of the present invention.

FIG. 2 is a cross-sectional view illustrating an electromagnetic wave shielding sheet according to another embodiment of the present invention.

FIG. 3 is an enlarged cross-sectional view along line Y-Y′ of FIG. 1.

FIG. 4 is an enlarged cross-sectional view along line X-X′ of FIG. 1.

FIG. 5 is a schematic diagram illustrating that a first fiber web and a second fiber web are integrated through a dot-shaped hot-melt member during a process of manufacturing an electromagnetic wave shielding sheet according to one embodiment of the present invention.

FIG. 6 is a schematic diagram illustrating that the first fiber web and the second fiber web are integrated through a grid-shaped hot-melt member during the process of manufacturing an electromagnetic wave shielding sheet according to one embodiment of the present invention.

### DETAILED DESCRIPTION OF THE EMBODIMENTS

Hereinafter, embodiments of the present invention will be fully described in detail, which is suitable for easy implementation by those skilled in the art to which the present invention pertains with reference to the accompanying drawings. The present invention may be implemented in various different forms, and thus it is not limited to embodiments which will be described herein. In the drawings, some portions not related to the description will be omitted in order to clearly describe the present invention, and the same or similar reference numerals are given to the same or similar components throughout this disclosure.

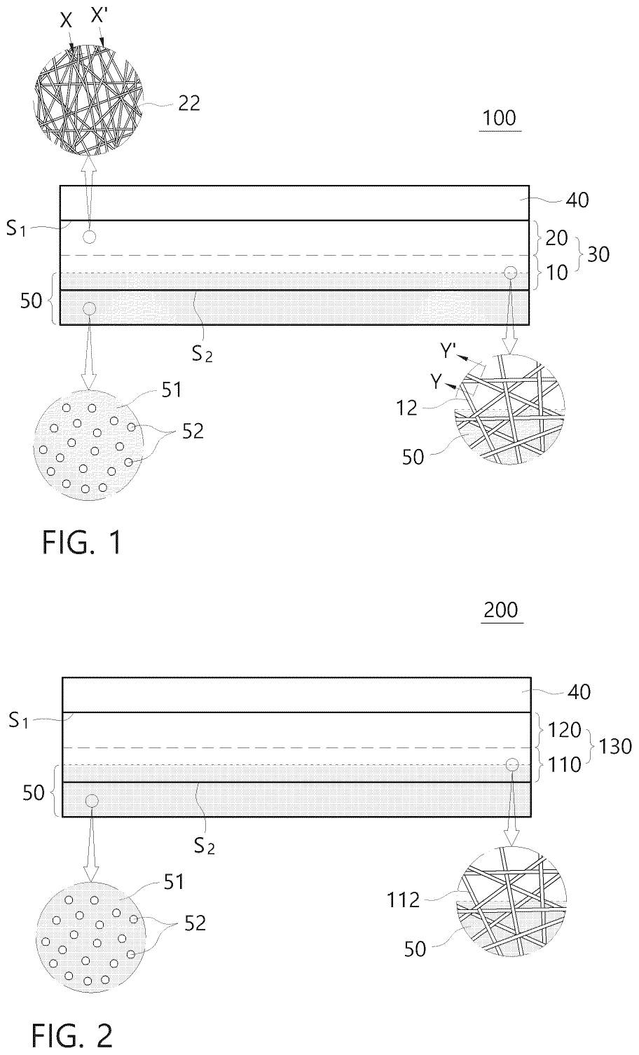

In describing with reference to FIGS. 1 and 2, electromagnetic wave shielding sheets 100 and 200 according to one embodiment of the present invention each include an electromagnetic wave shielding part 30 or 130 having first surfaces S₁ and second surfaces S₂ facing the first surface S₁ in a thickness direction, a cover member 40 disposed on the first surfaces S₁ of the electromagnetic wave shielding part 30 or 130, and a conductive adhesive member 50 of which a part of a thickness region is disposed on the second surfaces S₂ of the electromagnetic wave shielding part 30 or 130.

The electromagnetic wave shielding parts 30 and 130 each include a first conductive part 10 or 110 of which one surface is the second surface S₂, and a second conductive part 20 or 120 of which one surface is the first surface S₁ to have excellent vertical shielding performance, secure an adhering force and flexibility for an adherend surface having a curvature or step, and prevent electromagnetic waves from leaking in a lateral direction, and in order to increase an adhering force between the conductive adhesive members 50, which will be described below, and the first conductive parts 10 and 110, the first conductive parts 10 and 110 are formed of a conductive fiber web having a three-dimensional network structure formed of first metal-coated fibers 12 and 121, respectively.

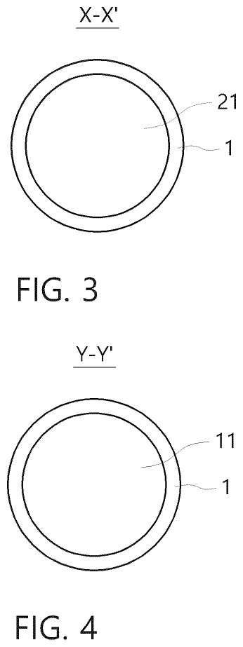

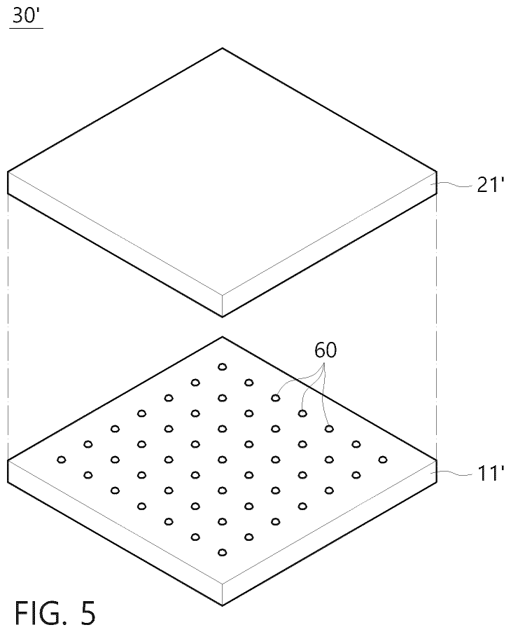

As shown in FIGS. 3 and 5, the first metal-coated fiber 12 may include a first fiber 11 and a metal layer 1 surrounding an outer surface of the first fiber 11. In addition, a the separately manufactured first metal-coated fiber 12 may form a three-dimensional network structure, but preferably, the three-dimensional network structure may be derived from the three-dimensional network structure formed of the first fiber 11. In other words, the first conductive parts 10 and 110 may be integrally formed so that the metal layer 1 covers inner and outer surfaces of a first fiber web 11′ with a predetermined thickness while maintaining the three-dimensional network structure of the first fiber web 11′ formed of the first fiber 11 as much as possible, thereby achieving lower resistance characteristics and high vertical and horizontal shielding performance. When the three-dimensional network structure is formed through separately manufactured first metal-coated fibers 12, an interface of contact points or surfaces between the first metal-coated fibers 12 may not be fixed and lifted, making it difficult to maintain a shape or increasing resistance. In order to prevent the problems, when a separate conductive adhesive is provided to fix the contact points or surfaces between the first metal-coated fibers 12, pore occlusion may occur due to the conductive adhesive, making it difficult to maintain the three-dimensional network structure and degrading flexibility. In addition, the overall thickness of the first conductive part may increase due to the conductive adhesive, which may not be desirable for implementing a thin-film electromagnetic wave shielding sheet.

In addition, a diameter of the first fiber 11 may range from 2 μm to 10 μm, and the first fiber web 11′ may have a basis weight range from 5 g/m² to 20 g/m², a porosity ranging from 30% to 70%, and a density ranging from 1 g/cm³ to 3 g/cm³. In this way, a higher level of mechanical strength is secured, which may be advantageous in preventing electromagnetic wave leakage through a side surface of the first conductive part without degrading workability and exhibiting improved vertical shielding performance. When the diameter of the first fiber is less than 2 μm, handleability may be degraded and it may not be easy to manufacture a nonwoven fabric, and sizes of open pores in the second surfaces S₂ of the first conductive parts 10 and 110 are small, making it difficult for the conductive adhesive members 50, which will be described below, to infiltrate to be disposed inside the first conductive parts 10 and 110. In addition, when the diameter of the first fiber 11 exceeds 10 μm, adhesion and flexibility to the adherend surface may be reduced, and there is a concern in that electromagnetic wave shielding performance may be degraded in the horizontal direction.

In addition, when the basis weight of the first fiber web 11′ is less than 5 g/m², a mechanical strength of the first fiber web is reduced, handling becomes difficult, and manufacturing may not be easy. In addition, when the basis weight exceeds 20 g/m², it may not be easy to form the metal layer on the outer surface of the first fiber located at a central portion in a thickness direction of the first fiber web, and there is a concern in that flexibility may also be degraded.

In addition, when the porosity of the first fiber web 11′ is less than 30%, there is a concern in that adhesion and flexibility to the adherend surface may be degraded, and an amount of the conductive adhesive member, which will be described below, infiltrating to be disposed through the second surface S₂ may be reduced, which may weaken a bonding force strength between the first conductive parts 10 and 110 and the conductive adhesive members 50. In addition, when the porosity exceeds 70%, a mechanical strength of the first conductive part may be degraded or subsequent processes may not be easy due to the weak mechanical strength.

In addition, when the density of the first fiber web 11′ is less than 1 g/cm³, there is a concern about a decrease in the mechanical strength of the first fiber web and a leakage of electromagnetic shielding to the side surface, and when the density exceeds 3 g/cm³, adhesion and flexibility may be degraded.

In addition, the first fiber 11 may be formed of a known material that can be typically manufactured in a fiber shape. For example, the first fiber 11 may include one or more compounds selected from the group consisting of polyester-based, polyurethane-based, polyolefin-based, polyamide-based, acrylic-based, and cellulose-based compounds, and as a more specific example, may be a polyester-based compound.

In addition, each of the first conductive parts 10 and 110 may have a thickness of 20 μm or less, as another example, ranging from 10 μm to 18 μm or 10 μm to 15 μm, and more specifically, 11 μm, which may be advantageous in achieving the objective of the present invention.

In addition, a typical metal material may be used as the metal layer 1 without limitation. For example, the metal layer may be formed of one or more metal materials selected from the group consisting of aluminum, nickel, copper, silver, gold, chromium, platinum, a titanium alloy, and stainless steel. For example, the metal layer 1 may include nickel and/or copper and, specifically, may be formed of three layers of nickel layer/copper layer/nickel layer. In this case, the copper layer has low electrical resistance to exhibit excellent electromagnetic wave shielding performance and may minimize cracks of the metal layer 1 even due to deformation such as wrinkling or stretching and improve elasticity characteristics. In addition, the nickel layer formed on the copper layer may prevent the electromagnetic wave shielding performance from being degraded by preventing oxidation of the copper layer.

In addition, the metal layer 1 may have a thickness ranging from 0.1 μm to 2 μm, and when a thickness of the metal layer 1 exceeds 2 μm, cracks and delamination may be likely to occur when the shape is deformed, and when the thickness is less than 0.1 μm, it may be difficult to exhibit the electromagnetic wave shielding performance at a desired level.

Next, the second conductive parts 20 and 120, which constitute the electromagnetic wave shielding part together with the first conductive parts 10 and 110, are described.

The first conductive parts 10 and 120, in addition to having the predetermined electromagnetic wave shielding performance, have various functions such as flexibility of the electromagnetic wave shielding sheets 100 and 200, adhesion to an adherend surface, and accommodating a portion of the conductive adhesive member 50 attached to the adherend surface inside to increase an interlayer bonding force and a contact between the conductive filler 52 in the conductive adhesive member 50 and the first metal-coated fiber 12 to reduce resistance, whereas the second conductive parts 20 and 120 serve as main parts that determine electromagnetic wave shielding performance of the electromagnetic wave shielding part.

To this end, as shown in FIG. 1, the second conductive part 20 may be a conductive fiber web formed of a second metal-coated fiber 22 having a smaller fiber diameter than the first metal-coated fiber, or as shown in FIG. 2, the second conductive part 120 may be a metal sheet.

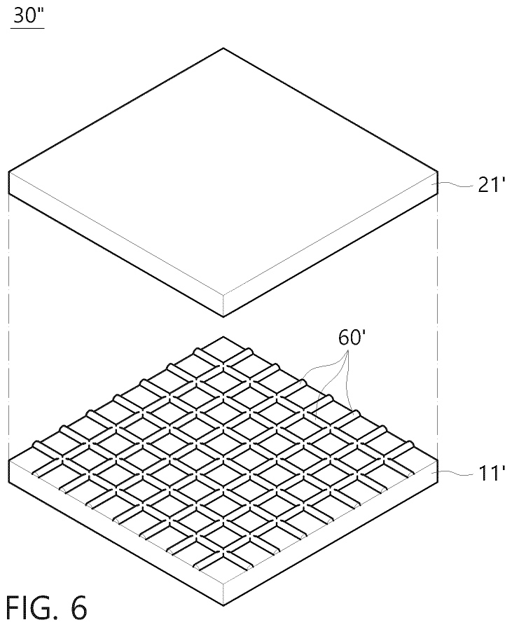

First, in describing the second conductive part 20 that is a conductive fiber web with reference to FIGS. 1 and 4 to 6, the second conductive part 20 may have a three-dimensional network structure formed of the second metal-coated fiber 22 of which the metal layer 1 is exposed to the outside. In addition, an average size of pores open on the first surface S₁ of the second conductive part 20 may be formed to be smaller than an average size of pores open on the second surface S₂ of the first conductive part 10, thereby exhibiting excellent shielding performance against electromagnetic waves. For example, an average size of pores in the second surface may range from 2 μm to 6 μm, and an average size of pores in the first surface may range from 0.2 μm to 2 μm, thereby exhibiting excellent electromagnetic wave shielding performance through the second conductive part 20 while further increasing the electromagnetic wave shielding performance through the first conductive part 10, and improving flexibility, adhesion to the adherend surface, and bonding characteristics with the conductive adhesive member 50.

In addition, the second conductive part 20 is disposed to occupy a predetermined thickness of the first conductive part 10 and the electromagnetic wave shielding part 30, and in this case, the metal layer 1 of the first conductive part 10 and the metal layer 1 of the second conductive part 20 may be formed integrally. In other words, the electromagnetic wave shielding part 30 may be a single body in which the first conductive part 10 and the second conductive part 20 are not manufactured independently and then stacked, but in which the first metal-coated fiber 12 and the second metal-coated fiber 22, whose fiber diameters are different and in which the metal layer 1 is exposed to the outside, are separately disposed in different regions in the thickness direction of the electromagnetic wave shielding part 30 to form an overall three-dimensional network structure. In this way, when the first conductive part 10 and the second conductive part 20 are integrated into a single body through the single metal layer 1, a conductive adhesive layer for attaching the first conductive part 10 and the second conductive part 20, which are independently manufactured, may be omitted, which is very advantageous in reducing the thickness, and is advantageous in preventing an increase in vertical resistance due to an interposition of the conductive adhesive layer in the middle and a decrease in electromagnetic wave shielding performance due to the interposition. In addition, the reduced thickness of the electromagnetic wave shielding part can improve heat dissipation characteristics in the thickness direction, and the non-use of the conductive adhesive layer is advantageous in further improving the heat dissipation characteristics. Furthermore, the conductive adhesive layer may degrade the electromagnetic wave shielding performance by guiding the electromagnetic waves to the side surface and causing a lateral leakage, but there is an advantage in that the electromagnetic waves can be prevented from leaking to the side surface due to the non-use of the conductive adhesive layer.

Meanwhile, the first fiber webs 11′ from which the first conductive part 10 is derived and second fiber webs 12′ from which the second conductive part 20 is derived may be integrated through the metal layers surrounding the outer and inner surfaces, but more preferably, a fusion part (not shown) derived from hot-melt adhesive members 60 and 60′ that fix the first fiber webs 11′ and the second fiber webs 21′ is further included, and the metal layers 1 may integrally cover the outer surfaces of the first fiber 11 and the second fiber 21 and the outer surface of the fusion part of stacks 30′ and 30″of the first fiber webs 11′ and the second fiber webs 21′, thereby making it advantageous for the electromagnetic wave shielding part 30 to stably maintain its shape without separation of the first conductive part 10 and the second conductive part 20 and to exhibit the electromagnetic wave shielding performance as an integral part. The fusion part may be formed through a plurality of dot-shaped hot-melt adhesive members 60 that are spaced from each other or a plurality of grid-shaped hot-melt adhesive members 60′ that are spaced from each other, thereby integrating the first fiber web 11′ and the second fiber web 21′ while minimizing pore occlusion at an interface between the two fiber webs, and further enhancing a bonding force through embossing characteristics. The hot-melt adhesive members 60 and 60′ may be known thermoplastic resins, for example, low-melting point polyesters or polyamide. The dot-shaped hot-melt adhesive member 60 or grid-shaped hot-melt adhesive member 60′ may have a melting point ranging from 80° C. to 160° C. and a thickness of 20 μm or less, which may be more advantageous in achieving the objective of the present invention. When the thickness of the dot-shaped hot-melt adhesive member 60 or grid-shaped hot-melt adhesive member 60′ exceeds 20 μm, pore occlusion at the interface between the first fiber web 11′ and the second fiber web 21′ may be excessive, and a thickness of the fusion part at the interface may increase, which may cause electromagnetic waves to leak through the fusion part. In addition, when the melting point of the dot-shaped hot-melt adhesive member 60 or grid-shaped hot-melt adhesive member 60′ is less than 80° C., there is concern that the interface between the first fiber web 11′ and the second fiber web 21′ may be separated due to a decrease in adhesive strength resulting from low-temperature bonding. In addition, when the melting point of the dot-shaped hot-melt adhesive member 60 or grid-shaped hot-melt adhesive member 60′ exceeds 160° C., there is concern that damage may occur due to heat applied to the first fiber web 11′ and the second fiber web 21′. Meanwhile, the dot-shaped hot-melt adhesive member 60 or grid-shaped hot-melt adhesive member 60′ may have a spacing between adjacent dots or between edges forming a grid ranging from 0.7 mm to 2.0 mm, which may be advantageous in minimizing pore occlusion while exhibiting sufficient adhesive characteristics.

In addition, a diameter of the second fiber 21 may be preferably less than 1 μm, more preferably, ranging from 100 nm to 800 nm, and the second fiber web 21′ may have a basis weight ranging from 1 g/m² to 10 g/m², more preferably, 2 g/m² to 8 g/m², and a porosity ranging 20% to 60%, more preferably, 30% to 50%, through which it is advantageous to further reduce the sizes of open pores in the surface of the first surface S₁ of the electromagnetic wave shielding part 30, and further increase the contact or bonding area between the second metal-coated fibers 22 so that it may be advantageous to exhibit electromagnetic wave shielding performance at a level close to that of a metal sheet with the same thickness.

In addition, known materials that can be implemented as fibers having less than 1 μm may be used as the first fiber 21 without limitation, and an example thereof may include one or more selected from the group consisting of polyurethane, polystyrene, polyvinyl alcohol, polymethyl methacrylate, polylactic acid, polyethyleneoxide, polyvinyl acetate, polyacrylic acid, polycaprolactone, polyacrylonitrile, polyvinylpyrrolidone, polyvinylchloride, polycarbonate, polyetherimide, polyethersulphone, polybenzimidazol, polyamide, polyethylene terephthalate, polybutylene terephthalate, and a fluorine-based compound. In addition, the fluorine-based compound may include one or more compounds selected from the group consisting of polytetrafluoroethylene (PTFE)-based, tetrafluoroethylene-perfluoroalkyl vinyl ether copolymer (PFA)-based, tetrafluoroethylene-hexafluoropropylene copolymer (FEP)-based, tetrafluoroethylene-hexafluoropropylene-perfluoroalkyl vinyl ether copolymer (EPE)-based, tetrafluoroethylene-ethylene copolymer (ETFE)-based, polychlorotrifluoroethylene (PCTFE)-based, chlorotrifluoroethylene-ethylene copolymer (ECTFE)-based, and polyvinylidene fluoride (PVDF)-based compounds. As a more specific example, the second fiber 21 may be, for example, PVDF.

In addition, the second conductive part 20 that is a conductive fiber web may have a thickness of 15 μm or less, as another example, range from 5 μm to 12 μm, and more specifically, 11 μm. When the thickness of the second conductive part 20 that is a conductive fiber web is less than 5 μm, the mechanical strength may be reduced, handling may be difficult, and manufacturing may not be easy. In addition, when the thickness exceeds 15 μm, there is concern that flexibility and elasticity may be degraded and it may not be desirable in terms of thinning.

Next, another type of the second conductive part 120 will be described with reference to FIG. 2. The second conductive part 120 may be a nonporous member having electromagnetic wave shielding performance, and preferably, may be a metal sheet. The metal sheet may be formed of a metal material containing one or more selected from the group consisting of copper, aluminum, silver, and gold. In addition, the metal sheet may have a thickness of 40 μm or less, as another example, ranging from 3 μm to 30 μm, which may be more advantageous in achieving the objective of the present invention.

In this case, a fusion part (not shown) derived from a hot-melt adhesive material that fixes between the metal sheet and the first fiber web included in the first conductive part 110 may be further included. The metal layer included in the first conductive part 110 may integrally cover the outer surface of the first fiber and an outer surface of the fusion part, thereby enabling the second conductive part 120 that is a metal sheet and the first conductive part 110 to implement an electromagnetic wave shielding part 130 integrally without a separate conductive adhesive layer. In this way, this is very advantageous in reducing the thickness by omitting the conductive adhesive layer and can prevent an increase in vertical resistance due to the conductive adhesive layer intervening in the middle and degradation in electromagnetic wave shielding performance due to the increase, the reduced thickness of the electromagnetic wave shielding part can improve heat dissipation characteristics in the thickness direction, and the non-use of the conductive adhesive layer can further improve the heat dissipation characteristics. Furthermore, the conductive adhesive layer may degrade the electromagnetic wave shielding performance by guiding the electromagnetic waves to the side surface and causing a lateral leakage, but there is an advantage in that the electromagnetic waves can be prevented from leaking to the side surface due to the non-use of the conductive adhesive layer.

Next, the conductive adhesive members 50 in which some portions of the thickness region are disposed on the second surfaces S₂ of the electromagnetic wave shielding parts 30 and 130, and the remaining thickness region is disposed inside the first conductive parts 10 and 110 of the electromagnetic wave shielding parts 30 and 130 will be described.

The conductive adhesive members 50 serve to fix the electromagnetic wave shielding sheets 100 and 200 on the adherend surfaces and are implemented to have conductivity in order to improve electromagnetic wave shielding and heat transfer characteristics. The conductive adhesive member 50 includes an adhesive component 51 and conductive fillers 52. Any known adhesive component may be used as the adhesive component 51 without limitation and may be, for example, a mixture of one or more of an acrylic-based resin, silicone-based resin, etc. In addition, the conductive filler 52 may be one or more selected from the group consisting of nickel, nickel-graphite, carbon black, graphite, aluminum, copper, and silver. In addition, the conductive adhesive member 50 may contain the conductive fillers 52 in an amount of 5 to 95 wt %, more preferably, 5 wt % to 20 wt %, based on the entire weight of the conductive adhesive member 50. In addition, the conductive filler 52 may have an average particle diameter ranging from 1 μm to 5 μm, but the present invention is not limited thereto.

In addition, the conductive adhesive member 50 may have a thickness ranging from 5 μm to 20 μm, as another example, 7 μm to 15 μm. In addition, 10% to 40% of the entire thickness of the conductive adhesive member 50 may be located inside the first conductive parts 10 and 110, thereby increasing a bonding force between the conductive adhesive members 50 and the electromagnetic wave shielding parts 30 and 130 and increasing contact characteristics between the conductive fillers 52 and the first metal-coated fiber 12, which may be advantageous in reducing the vertical resistance.

Next, the cover members 40 disposed on the first surfaces S₁ of the electromagnetic wave shielding parts 30 and 130 will be described.

The cover member 40 performs a function of protecting the surfaces of the second conductive parts 20 and 120 of the electromagnetic wave shielding parts 30 and 130 from the external physical and chemical environment. In addition, the cover member 40 may be formed to have adhesive characteristics of being attached to an adherend surface. In addition, since the electromagnetic wave shielding performance of the electromagnetic wave shielding sheets 100 and 200 may exhibit excellent characteristics when the vertical resistances of the electromagnetic wave shielding parts 30 and 130 are low while the overall vertical resistances of the electromagnetic wave shielding sheets 100 and 200 are high, the cover member 40 may be formed to have low dielectric characteristics and/or high electrical resistance insulating characteristics to implement high overall vertical resistance. For example, when the cover member 40 is formed to have both insulating and adhesive characteristics, the cover member 40 may be formed using an acrylic resin or a silicone resin. Alternatively, the cover member 40 may have hot-melt characteristics to be easily fixed to the electromagnetic wave shielding parts 30 and 130 using heat. Alternatively, the cover member 40 may have adhesive characteristics and may not adhere to an adherend surface of a specific material due to a lack of or low adhesive strength, but may have material selective adhesive characteristics that adhere to other materials. This may be advantageous in improving workability because, when disposed on a predetermined adhesion surface, the electromagnetic wave shielding sheets 100 and 200 have low adhesive characteristics on a surface of a pickup jig to be easily separated, but bas excellent adhesive strength to an adherend surface to be prevented from being delaminated after attachment. The material-selective adhesive characteristics may be designed according to a type of specific material requiring low or zero adhesive strength, and thus the present invention is not particularly limited thereto. For example, the cover member with the material selective adhesive characteristics may be a cured at least one of epoxy resin and acrylic resin with low or no adhesive characteristics on a urethane-based material.

In addition, the cover member 40 may have a thickness ranging from 5 μm to 20 μm, as another example, 8 μm to 15 μm.

Each of the electromagnetic wave shielding sheets 100 and 200 may be formed into a thin

film with an entire thickness of 45 μm or less, as another example, ranging from 30 μm to 45 μm, and as a specific example, 40 μm, and the electromagnetic wave shielding part has a thickness ranging from 15 to 25 μm, and in this way, sufficient flexibility can be secured through a small thickness despite having the first conductive part. In addition, the thinned electromagnetic wave shielding sheet may be more advantageous for use in electronic devices such as tablet personal computers (PCs) and smartphones that are becoming slimmer. In addition, as an example, the electromagnetic wave shielding sheet 100 having a thickness of 40 μm and a second conductive part of a conductive fiber web has vertical resistance of 230±70 mΩ, which may exhibit electromagnetic wave shielding performance close to that achieved when a second conductive part of a metal sheet is used.

The electromagnetic wave shielding sheets 100 and 200 may be manufactured by a manufacturing method which will be described below, but the present invention is not limited thereto.

Specifically, the electromagnetic wave shielding sheets 100 and 200 may be manufactured by manufacturing the electromagnetic wave shielding parts 30 and 130 including the first conductive parts 10 and 110, which have a three-dimensional network structure formed of the first metal-coated fiber 12 having the first surface S₁ and the second surface S₂ facing the first surface S₁ in the thickness direction, one surface being the second surface S₂, and the metal layer 1 exposed to the outside, and the second conductive parts 20 and 120 having one surfaces being the first surfaces S₁, bringing the second surfaces S₂ of the electromagnetic wave shielding parts 30 and 130 into contact with the conductive adhesive members 50 and then pressing the second surfaces S₂ and the conductive adhesive members 50 such that a part of an entire region of the conductive adhesive members 50 is located inside the first conductive parts 10 and 110, and arranging the cover members 40 on the first surfaces S₁ of the electromagnetic wave shielding parts 30 and 130.

First, in describing the second conductive parts 20 and 120 are manufactured from second fiber web 21′, the manufacturing of the electromagnetic wave shielding parts 30 and 130 may include operation (1) of stacking the second fiber web 21′, which is formed of the second fiber 21 having a smaller diameter than the first fiber 11 for forming the second conductive part 20, on one surface of the first fiber web 11′ formed of first fiber 11 for forming the first conductive part 10, and operation (2) of integrally electroless plating stacks 30′ and 30″ of the stacked first fiber web 11′ and second fiber web 21′ and forming the metal layer 1 surrounding the outer surface of each of the first fiber 11 and the second fiber 21.

The first fiber web 11′ may be manufactured through a known manufacturing method of manufacturing a nonwoven fabric, and for example, the first fiber may be manufactured by processing dry nonwoven fabrics, such as chemical bonding nonwoven fabrics, thermal bonding nonwoven fabrics, air-lay nonwoven fabrics, wet nonwoven fabrics, spanless nonwoven fabrics, or needle-punched nonwoven fabrics, or by a known method such as a melt-blown method. In addition, the second fiber web 21′ may also be manufactured by the above method or by a calendering process performed on a fiber mat formed by accumulating second fibers spun through electrospinning.

In addition, operation (1) may include arranging the dot-shaped hot-melt adhesive member 60 or the grid-shaped hot-melt adhesive member 60′ between the first fiber web 11′ and the second fiber web 21′, and melting the hot-melt adhesive members 60 and 60′ to fuse the first fiber web 11′ and the second fiber web 21′. In this case, the fusion may be achieved by solidifying the hot-melt adhesive member melted by applying heat or ultrasonic waves. In this case, the application of the heat or ultrasonic waves may be performed through known conditions, and the present invention is not particularly limited thereto.

Thereafter, as operation (2), an operation of integrally electroless plating the stacks 30′ and 30″ of the first fiber web 11′ and the second fiber web 21′ to form the metal layer 1 on the outer surface of each of the first fiber 11 and the second fiber 21 and additionally on an outer surface of a fusion part when the fusion part is further included between the first fiber web 11′ and the second fiber web 21′ may be performed.

The electroless plating may include operation 2-1) of immersing the stacks 30′ and 30″ in a catalyst solution to perform catalytic treatment, operation 2-2) of activating the catalytic-treated stacks 30′ and 30″, and operation 2-3) of forming the metal layer 1 by electroless plating the activated laminate stacks 30′ and 30″, and in this case, an operation of degreasing or hydrophilizing the stacks 30′ and 30″ before performing operation (2) is further included.

The degreasing is an operation of washing away oxides or foreign materials, especially oil and grease, present on surfaces of the stacks 30′ and 30″ by treating the oxides or foreign materials with an acid or alkaline surfactant. When foreign materials are present on the surfaces of the stacks 30′ and 30″, the catalyst or a chemical reaction during the activating may be inhibited due to the foreign materials or a void phenomenon so that the metal layer plating may not be formed uniformly, and even when the plating is performed, a bonding force between the plated surface and the metal layer may be very poor, which may significantly degrade product reliability. However, when the acid or alkaline surfactant used in the degreasing is not completely washed off, it may act as a contaminant for a subsequent treatment solution (a catalyst solution or activation solution) so that the surfactant should be sufficiently washed off at an appropriate temperature and pressure.

When materials of the stacks 30′ and 30″ are hydrophobic, the hydrophilizing is an operation of converting the hydrophobic materials of the stacks 30′ and 30″ to hydrophilic materials and, simultaneously, introducing functional groups such as carboxyl groups, amine groups, and hydroxyl groups to the surfaces of the stacks 30′ and 30″ to facilitate adsorption of metal ions and form fine cavities on the surfaces of the stacks 30′ and 30″, and increasing surface roughness to improve an adhesive strength adhesion between the precipitated metal layer and the surfaces of the stacks 30′ and 30″. The hydrophilizing may be performed by mixing an alkali metal hydroxide or a nitrogen compound with a surfactant, and sodium hydroxide (NaOH) or potassium hydroxide (KOH) may be used as the hydroxide and the nitrogen compound may include an ammonium salt or an amine compound. An ammonium salt substituted with an alkyl group or aryl group, for example, such as ammonium hydroxide, ammonium chloride, ammonium sulfate, ammonium carbonate or triethylammonium salt, tetraethylammonium salt, trimethylammonium salt, tetramethylammonium salt, trifluoro ammonium salt, or tetrafluoro ammonium salt may be used as the ammonium salt, and an aliphatic amine compound, for example, such as methylamine, ethylamine, dimethylamine, diethylamine, trimethylamine, ethylenediamine, diethylenetriamine, or a urea and hydrazine derivative may be used as the amine compound. The surfactant may use an anionic surfactant, a cationic surfactant, or a neutral surfactant, such as sodium alkyl sulfonate (SAS), sodium alkyl sulfate ester (AS), sodium olefin sulfonate (AOS), or alkyl bezene sulfonate (LAS). In this case, the hydrophilizing may be performed by immersing the stacks 30′ and 30″ in a hydrophilization solution containing the compounds at a temperature ranging 20° C. to 100° C. for about 2 to 20 minutes.

Operation 2-1) is an operation of performing catalyzing treatment to facilitate plating by precipitating catalyst particles on the surfaces of the stacks 30′ and 30″ undergoing the degreasing and hydrophilizing.

The catalyst solution contains one or more compounds selected from the group consisting of salts of Ti, Sn, Au, Pt, Pd, Ni, Cu, Ag, Al, Zn, and Fe, and the catalyst solution may contain a colloidal solution consisting of salts of Ti, Sn, Au, Pt, Pd, Ni, Cu, Ag, Al, Zn and Fe, or a noble metal complex ion. For example, a solution containing 50 to 250 ml of hydrochloric acid, 50 to 300 g of sodium chloride or potassium chloride, 5 to 60 g of tin chloride (SnCl₂), and 0.1 to 5 g of palladium chloride (PdCl₂) per one liter of ultra deionized water may be used as the colloidal solution.

In this case, in order to improve adsorption efficiency of the catalyst particles before performing operation 2-1), a pre-dip process may be performed as a preliminary catalyst treatment process, and the pre-dip process may prevent the catalyst solution used in the catalyst treatment from being contaminated or changed in its concentration by immersing the stacks 30′ and 30″ in a low-temperature catalyst solution prior to the catalyzing treatment.

Next, operation 2-2) of activating the catalyst-treated stacks 30′ and 30″ is performed.

The activating is an operation of improving activity of the adsorbed metal particles and a precipitation behavior of the electroless plating solution after the catalyzing. Through the activating, the metal particles surrounding the colloidal particles are removed to leave only the adsorbed catalyst, thereby facilitating the precipitation of the metal layer through the electroless plating. For example, the activating process may be an operation of immersing the stacks 30′ and 30″ in a mixed solution of distilled water and sulfuric acid for 30 seconds to 5 minutes.

Next, operation 2-3) of forming the metal layer on the activated stacks 30′ and 30″ through electroless plating is performed.

The electroless plating may generally be divided into a reduction plating method and a displacement plating method. The reduction plating method is a method in which a metal is precipitated through a reduction reaction and plated on a surface of a substrate, and the displacement plating method is a method in which a metal with a relatively high reduction power is precipitated and plated due to a difference in a reduction power of the metal. The operation 2-3) may use, for example, the displacement plating method.

The displacement plating method is a plating method of immersing the stacks 30′ and 30″ in a primary plating solution having a relatively low reduction power and then immersing the stacks 30′ and 30″ in a secondary plating solution having a relatively high reduction power to precipitate the metal of the secondary plating solution. The above primary and secondary plating solutions may each contain a metal selected from the group consisting of Ti, Sn, Au, Pt, Pd, Ni, Cu, Ag, Al, Zn, and Fe and, preferably, the primary plating solution may contain Ni ions, and the secondary plating solution may contain Cu ions. The displacement plating method may ultimately manufacture a conductive fiber web in which the metal layer 1 is formed integrally by immersing the stacks 30′ and 30″ at a temperature ranging from 30 to 70° C. for 1 to 10 minutes.

Alternatively, when the second conductive part 120 is a metal sheet, the electromagnetic wave shielding part 130 may be manufactured by operation (A) of stacking a metal sheet as the second conductive part on one surface of the first fiber web formed of first fibers for forming the first conductive part, and operation (B) of integrally electroless plating the stacked first fiber web and metal sheet to form a metal layer surrounding an outer surface of the first fiber. In this case, like operation (1), operation (A) may be implemented to include an operation of arranging a dot-shaped hot-melt adhesive member or a grid-shaped hot-melt adhesive member between the first fiber web 11′ and the metal sheet, and an operation of melting the hot-melt adhesive member to fuse the first fiber web 11′ and the metal sheet. In addition, operation (B) may be performed in the same manner as operation (2), and thus a detailed description thereof will be omitted.

Thereafter, an operation of arranging the conductive adhesive members 50 and the cover members 40 on the second surfaces S₂ and the first surfaces S₁ of the manufactured electromagnetic wave shielding parts 30 and 130 is performed.

First, to describe the operation of arranging the conductive adhesive member 50, an operation of arranging and pressing the conductive adhesive member such that a part of an entire region of the conductive adhesive member is located inside the first conductive part. The conductive adhesive member may be directly applied onto the second surface S₂ in an undried composition state, or a conductive adhesive member in a dried state with a predetermined thickness on a release film may be separately stacked on the second surface S₂.

The conductive adhesive member 50 in an undried composition state may include an adhesive resin, a conductive filler, a solvent or a dispersant and may further include additives such as other known leveling agents, plasticizers, ultraviolet blockers, antioxidants, and antistatic agents. The adhesive resin may be, for example, a silicone-based adhesive resin or an acrylic-based adhesive resin. The conductive filler may include one or more selected from the group consisting of nickel, nickel-graphite, carbon black, graphite, aluminum, copper, and silver.

After the conductive adhesive member 50 is disposed on the second surface S₂, portions of the conductive adhesive member 50 may be pressed to be located inside the first conductive parts 10 and 110, and when curing a portion or entirety of the conductive adhesive member 50 is required, heat may be applied together with a pressure. The applied pressure may be appropriately selected in consideration of the thickness, porosity, and pore diameter of the first conductive parts 10 and 110, and viscosity when the conductive adhesive member is in a composition state, and the applied heat may also be appropriately selected in consideration of a composition of the conductive adhesive member, and therefore the present invention is not particularly limited thereto.

In addition, to describe the operation of arranging the cover member 40, the operation may be performed by arranging prepared cover members on the first surfaces S₁ of the electromagnetic wave shielding parts 30 and 130 and then applying a predetermined pressure, heat, and/or ultrasonic waves. In this case, when the cover member 40 is a material selective adhesive member, the material-selective adhesive member may be disposed on the first surface S₁ and then attached by applying heat or ultrasonic waves. In addition, when the cover member 40 is an insulating adhesive member, the insulating adhesive member may be directly processed on the first surface S₁ in an undried composition state, or an adhesive member having a predetermined thickness on a release film in a dried state may be separately stacked on the first surface S₁.

### Modes of the Invention

The present invention will be described in more detail through the following examples, but the following examples do not limit the scope of the present invention, and this should be construed to help understanding of the present invention.

### Example 1

A fiber web to be implemented as a first conductive part was prepared. The prepared fiber

web contained poly (ethylene terephthalate) (PET) fibers with an average diameter of 8 μm and had a basis weight of 14.5 g/m², a porosity of 55%, and a density of 0.72 g/cm³.

In addition, a nanofiber web to be implemented as a second conductive part was prepared. Specifically, the nanofiber web was prepared by dissolving 12 g of polyvinylidene fluoride (PVDF) in 85 g of dimethylacetamide and acetone at a weight ratio of 70:30 at a temperature of 80° C. for 6 hours using a magnetic bar to prepare a spinning solution. The spinning solution was put into a solution tank of an electrospinning device and discharged at a speed of 20 uμ/min/hole. In this case, a temperature of a spinning section was maintained at 30° C. and humidity was maintained at 50%, a distance between a collector and a spinning nozzle tip was set to 20 cm, and a high-voltage generator was used above the collector to apply a voltage of 40 kV to a spin nozzle pack, while simultaneously applying an air pressure of 0.03 MPa of per spin pack nozzle to manufacture a PVDF nanofiber mat. Next, a calendaring process was performed at a temperature of 140° C. and a pressure of 1 kgf/cm² to dry the solvent and moisture remaining in the nanofiber mat, thereby manufacturing a nanofiber web having an average nanofiber diameter of 480 nm, a basis weight of 7.2 g/m², and a porosity of 45%.

Thereafter, a dot-shaped hot-melt adhesive member made of polyurethane (PU)-based material with a diameter and a thickness of 5 μm and 5 μm, respectively, and disposed at horizontal and vertical intervals of 1 mm and 1 mm, respectively, was disposed on the prepared fiber web, and then a nanofiber web was disposed on the dot, and heat and pressure were applied at a temperature of 120° C. and 5 kgf/cm² to manufacture an integrated fiber web/nanofiber web stack.

Afterwards, a nickel metal shell was formed on the fibers of the fiber web/nanofiber web stack. Specifically, nickel electroless plating was performed on the fiber web/nanofiber web stack. To this end, the fiber web/nanofiber web stack was immersed in a degreasing solution at a temperature of 60° C. for 30 seconds, washed with deionized water, immersed in an etching solution (5 M NaOH and deionized water) at a temperature of 60° C. for 1 minute again, and then washed with deionized water. Thereafter, the stack was immersed in a catalyst solution (0.9% Pd, 20% HCl, and deionized water) at room temperature for 3 minutes and then washed with deionized water. Thereafter, the stack was immersed in a sulfuric acid solution (H₂SO₄ 85 ml/L and deionized water) at a temperature of 50° C. for 30 seconds for catalytic activity and then washed with deionized water. Then, the fiber web/nanofiber web stack was immersed in a nickel ion solution at a temperature of 60° C. for 1 minute and 30 seconds and washed with deionized water so that a nickel metal shell with a thickness of 0.2 μm was coated on the fibers of the fiber web/nanofiber web stack, and therefore, an electromagnetic wave shielding part was manufactured such that the entire thickness was 19 μm, the first conductive part derived from the fiber web had a thickness of 11 μm and an average size of pores in the surface of 4.8 μm, and the second conductive part derived from the nanofiber web had a thickness of 8 μm and an average size of pores in the surface of 1.1 μm.

Thereafter, a conductive adhesive-forming composition, in which 7 parts by weight of nickel particles having an average particle diameter of 3 μm were mixed with 100 parts by weight of an acrylic adhesive-forming component, was coated on a release PET film using a bar coater, and the dried conductive adhesive was laminated onto the second surface of the electromagnetic wave shielding part, which was the first conductive part of the electromagnetic wave shielding part, and a calendaring process was performed so that the conductive adhesive member infiltrated into the first conductive part of the electromagnetic wave shielding part and occupied some thickness, and a heat curing process was performed at a temperature of 120° C. for 24 hours to manufacture an electromagnetic wave shielding sheet in which the conductive adhesive member was arranged so as to occupy 2.5 μm of the second surface of a thickness of the first conductive part of the conductive shielding part.

### Example 2

An electromagnetic wave shielding sheet was manufactured by performing the same operation as in Example 1, but instead of integrating the fiber web and the nanofiber web, electroless plating was performed on each of the fiber web and the nanofiber web to independently implement the first conductive part and the second conductive part, and then arranging the same dot-shaped hot-melt adhesive member between the first conductive part and the second conductive part and thermally bonding them to manufacture a conductive shielding part.

### Example 3

An electromagnetic wave shielding sheet was manufactured by performing the same process as in Example 2, but through manufacture of a conductive shielding part by processing the conductive adhesive-forming composition disclosed in Example 1 between the independently implemented first conductive part and second conductive part to form a conductive adhesive part.

### Comparative Example 1

An electromagnetic wave shielding sheet was manufactured by performing the same operation as in Example 1, except that the nanofiber web was omitted and the fiber web was changed to have a thickness of 19 μm, thereby manufacturing an electromagnetic wave shielding sheet in which the electromagnetic wave shielding part was formed of the first conductive part.

### Comparative Example 2

An electromagnetic wave shielding sheet was manufactured by performing the same operation as in Example 1, except that the fiber web was omitted and the nanofiber web was changed to have a thickness of 19 μm, thereby manufacturing an electromagnetic wave shielding sheet in which the electromagnetic wave shielding part was formed of the second conductive part.

### Experimental Example

The following physical properties were measured for the electromagnetic wave shielding sheets according to examples and comparative examples, and the results are shown in the following Table 1.

### 1. Evaluation of Electromagnetic Wave Shielding Performance

The electromagnetic wave shielding performance was measured in the frequency range from 30 MHz to 1.5 GHz following ASTM D4935, and the average electromagnetic wave shielding performance (dB) within the frequency range was calculated. Thereafter, the remaining electromagnetic wave shielding performances were expressed as a relative percentage based on 100% of the electromagnetic wave shielding performance of Comparative Example 1, and a percentage higher than 100% is interpreted as superior electromagnetic wave shielding performance compared to Comparative Example 1.

### 2. Evaluation of Flexibility

The electromagnetic wave shielding sheet was attached to a circuit board on which a chip with a thickness of 5 mm was mounted so as to cover an entire surface of the chip. The circuit board was then cut so as to divide an upper surface of the chip into two, and a degree to which the electromagnetic wave shielding sheet was close contact of a side surface of the chip was observed. Specifically, a thickness ratio of the chip thickness to the electromagnetic wave shielding sheet was calculated.

### 3. Evaluation Whether Conductive Shielding Part is Delaminated

The conductive adhesive part of the conductive shielding part was attached to a stainless steel (SUS) plate, and a PET film was attached to an opposite side of the conductive shielding part. The PET film was delaminated using a universal material testing machine, and a delamination pattern, including whether the first conductive part and the second conductive part of the conductive shielding part were delaminated, was observed.

TABLE 1

| | | | | Comparative | Comparative |
|---|---|---|---|---|---|
| | Example 1 | Example 2 | Example 3 | Example 1 | Example 2 |
| Average pore | 4.8/11 | 4.8/11 | 4.8/11 | 4.8/19 | Not prepared |
| diameter | | | | | |
| (μm)/thickness | | | | | |
| (μm) of surface | | | | | |
| of first | | | | | |
| conductive part | | | | | |
| Average pore | 1.1/8 | 1.1/8 | 1.1/8 | Not prepared | 1.1/19 |
| diameter | | | | | |
| (μm)/thickness | | | | | |
| (μm) of surface | | | | | |
| of second | | | | | |
| conductive part | | | | | |
| Attachment type | First | First | First | — | — |
| of first | conductive | conductive | conductive | | |
| conductive part | part metal | part metal | part metal | | |
| and second | layer and | layer and | layer and | | |
| conductive part | second | second | second | | |
| | conductive | conductive | conductive | | |
| | part metal | part metal | part metal | | |
| | layer are | layer are | layer are | | |
| | formed | bonded using | bonded using | | |
| | integrally | dot-shaped hot | conductive | | |
| | | melt | adhesive. | | |
| Electromagnetic | 216 | 115 | 180 | 100 | 220 |
| wave shielding | | | | | |
| performance (%) | | | | | |
| Flexibility (%) | 98.2 | 82.1 | 98.5 | 86.8 | 98.2 |
| Delamination | Partial | Partial | Delamination | Tearing of | Separation at |
| characteristics | tearing of | tearing of | between first | upper | interface |
| | second | second | conductive | surface of | between |
| | conductive | conductive | part and | conductive | conductive |
| | part of | part of | second | shielding | shielding part |
| | conductive | conductive | conductive | part | and conductive |
| | shielding | shielding | part | | adhesive |
| | part | part | | | member |

As can be seen in Table 1,

Examples 1 to 3 have superior electromagnetic wave shielding performance compared to Comparative Example 1 in which the electromagnetic wave shielding part is made of only the first conductive part. However, in the case of Comparative Example 2 in which the electromagnetic wave shielding part was formed of only the second conductive part, the electromagnetic wave shielding performance somewhat superior to that of Example 1 was exhibited, but as the result of evaluating the delamination characteristics, an interface separation occurred between the conductive shielding part and the conductive adhesive member, and therefore, degradation in the electromagnetic wave shielding performance is expected due to delamination of the electromagnetic wave shielding part during use.

Meanwhile, even in the case in which the electromagnetic wave shielding part formed the first conductive part and the second conductive part is provided through Examples 1 to 3, the electromagnetic wave shielding performance significantly varies according to a coupling form of the first conductive part and the second conductive part, and in particular, it can be seen that the electromagnetic wave shielding performance of Example 2, in which the first conductive part and the second conductive part, which were manufactured independently, were attached through the dot-shaped hot-melt adhesive member, was significantly degraded compared to Example 1 in which the metal layer formed on the fiber was integrally formed, and it can be presumed that this is due to electromagnetic waves leaking through the hot-melt adhesive member. In addition, it can be confirmed that Example 3 in which the first conductive part and the second conductive part are attached using the conductive adhesive member, also has poor electromagnetic wave shielding performance compared to Example 1.

Meanwhile, it can be seen that the flexibility of Example 2 is lower than the flexibility of Example 1, and as the result of evaluating the delamination characteristics, it is expected that, in Example 3, the first conductive part and the second conductive part are delaminated, and during use, there is lifting or delamination between the first conductive part and the second conductive part, and therefore, the electromagnetic wave shielding performance is degraded.

Although exemplary embodiments of the present invention have been described, the spirit of the present invention is not limited to the exemplary embodiments disclosed herein, and it should be understood that numerous other embodiments can be devised by those skilled in the art that will fall within the same spirit and scope of the present invention through addition, modification, deletion, supplement, and the like of a component, and also these other embodiments will fall within the spirit and scope of the present invention.

What is claimed is:

1. An electromagnetic wave shielding sheet, comprising:
an electromagnetic wave shielding part having a first surface and a second surface facing the first surface in a thickness direction and comprising a first conductive part and a second conductive part, wherein one surface of the first conductive part is the second surface and the first conductive part has a three-dimensional network structure formed of a first metal-coated fiber, wherein a metal layer of the first metal-coated fiber is exposed to an outside, and one surface of the second conductive part is the first surface;
a cover member disposed on the first surface of the electromagnetic wave shielding part; and
a conductive adhesive member, wherein a part of an entire thickness region of the conductive adhesive member is disposed on the second surface of the electromagnetic wave shielding part, and a remaining thickness region is disposed inside the second conductive part.

2. The electromagnetic wave shielding sheet according to claim 1, wherein an entire thickness is at most 45 μm, and the electromagnetic wave shielding part has a thickness ranging from μm 15 μm to 25 μm.

3. The electromagnetic wave shielding sheet according to claim 1, wherein the second conductive part has a three-dimensional network structure formed of a second metal-coated fiber, wherein a metal layer of the second metal-coated fiber is exposed to the outside, and a size of an open pore in the first surface is formed to be smaller than a size of an open pore in the second surface of the first conductive part.

4. The electromagnetic wave shielding sheet according to claim 3, wherein an average size of pores in the second surface ranges from 2 μm to 6 μm, and an average size of pores in the first surface ranges from 0.2 μm to 2 μm.

5. The electromagnetic wave shielding sheet according to claim 3, wherein the metal layer of the first conductive part and the metal layer of the second conductive part are formed integrally.

6. The electromagnetic wave shielding sheet according to claim 3, wherein
the first conductive part comprises a first fiber web formed of a first fiber;
the second conductive part comprises a second fiber web formed of a second fiber;
a fusion part configured to fix the first fiber web and the second fiber web is further comprised; and
the metal layer integrally covers outer surfaces of the first fiber and the second fiber of the stacked first fiber web and second fiber web and an outer surface of the fusion part.

7. The electromagnetic wave shielding sheet according to claim 1, wherein a thickness of the metal layer ranges from 0.1 μm to 2 μm.

8. The electromagnetic wave shielding sheet according to claim 1, wherein the metal layer is formed of at least one metal material selected from the group consisting of aluminum, nickel, copper, silver, gold, chromium, platinum, a titanium alloy, and stainless steel.

9. The electromagnetic wave shielding sheet according to claim 6, wherein a diameter of the first fiber ranges from 2 μm to 10 μm, and the first fiber web has a basis weight ranging from 5 g/m² to 20 g/m² and a porosity ranging from 30% to 70%.

10. The electromagnetic wave shielding sheet according to claim 6, wherein a diameter of the second fiber is less than 1 μm, and the second fiber web has a basis weight ranging from 1 g/m² to 10 g/m² and a porosity ranging from 20% to 60%.

11. The electromagnetic wave shielding sheet according to claim 6, wherein the fusion part is formed through a plurality of dot-shaped hot-melt adhesive members or grid-shaped hot-melt adhesive members, the plurality of dot-shaped hot-melt adhesive members or grid-shaped hot-melt adhesive members are spaced apart from each other.

12. The electromagnetic wave shielding sheet according to claim 1, wherein a thickness of the conductive adhesive member located inside the first conductive part is 10% to 40% of the entire thickness of the conductive adhesive member.

13. The electromagnetic wave shielding sheet according to claim 1, wherein the conductive adhesive member contains an adhesive component and conductive fillers dispersed in the adhesive component and having 5 wt % to 20 wt % of an entire weight of the conductive adhesive member.

14. The electromagnetic wave shielding sheet according to claim 1, wherein the cover member is a material-selective adhesive member, wherein the material-selective adhesive member is not adhered to an adherend surface of a material.

15. A method of manufacturing an electromagnetic wave shielding sheet, comprising:
manufacturing an electromagnetic wave shielding part having a first surface and a second surface facing the first surface in a thickness direction and comprising a first conductive part and a second conductive part, wherein one surface of the first conductive part is the second surface and the first conductive part has a three-dimensional network structure formed of a first metal-coated fiber-of which, wherein a metal layer of the first metal-coated fiber is exposed to an outside, and one surface of the second conductive part is the first surface;
pressing a conductive adhesive member disposed on the second surface of the electromagnetic wave shielding part, wherein a part of an entire region of the conductive adhesive member is located inside the first conductive part; and
arranging a cover member on the first surface of the electromagnetic wave shielding part.

16. The method according to claim 15, wherein the step of manufacturing of the electromagnetic wave shielding part comprises:
operation of stacking a second fiber web formed of a second fiber having a smaller diameter than a first fiber for forming the second conductive part on one surface of a first fiber web formed of the first fiber for forming the first conductive part; and
operation of forming a metal layer surrounding an outer surface of each of the first fiber and the second fiber by integrally electroless plating the stacked first fiber web and second fiber web.

17. The method according to claim 16, wherein the operation comprises:
arranging a dot-shaped or grid-shaped hot-melt adhesive member between the first fiber web and the second fiber web; and
melting the dot-shaped or grid-shaped hot-melt adhesive member to fuse the first fiber web and the second fiber web.

18. The method according to claim 17, wherein the dot-shaped or grid-shaped hot-melt adhesive member has a melting point ranging from 80° C. to 160° C. and an at most thickness of 20 μm.

19. An electronic device comprising the electromagnetic wave shielding sheet according to claim 1.

20. The electromagnetic wave shielding sheet according to claim 3, wherein a thickness of the metal layer ranges from 0.1 μm to 2 μm.
